(19) United States
(12) Patent Application Publication
(10) Pub. No.: US 2026/0338838 A1
(43) Pub. Date: Oct. 29, 2026

(54) CURRENT SENSE CIRCUIT FOR SWITCHING CONVERTER, INTEGRATED CIRCUIT INCLUDING THE SAME, AND CURRENT SENSE METHOD

(71) Applicant: Monolithic Power Systems, Inc., Kirkland, WA (US)

(72) Inventors: Wei-Chung Chen, Zhubei City (TW); Yu-Huei Lee, Xizhi District (TW)

(21) Appl. No.: 19/193,518

(22) Filed: Apr. 29, 2025

(51) Int. Cl. G01R 19/165; H02M 3/156

(52) U.S. Cl. CPC G01R 19/16571; H02M 3/156

(57) ABSTRACT

A current sense circuit for a switching converter including first and second switches is provided. The current sense circuit includes a sensing input terminal, an amplifier circuit, a sensing resistor, and a current-limiting circuit. The sensing input terminal is configured to be coupled to a terminal of the second switch to receive a first signal. The amplifier circuit has a first input terminal coupled to the sensing input terminal to receive the first signal and an output terminal configured to provide a current sense signal indicating a current flowing through the second switch in response to the first signal when the second switch is turned on. The sensing resistor is coupled between the first input terminal and the output terminal. The current-limiting circuit is coupled in series with the sensing resistor and configured to limit a current flowing through the sensing resistor when the first switch is turned on.

### BACKGROUND

### Field of Invention

The present application relates to current sense circuits for switching converters, integrated circuits including the same, and current sense methods.

### Description of Related Art

Switching converter, such as Switching Mode Power Supply (SMPS) is widely used for converting an input voltage to an output voltage and supplying a load due to its many advantages such as high efficiency, high current carrying ability and so on. A SMPS has at least one power switch, and the output voltage is regulated at least by controlling the ON and OFF actions of the power switch. A SMPS may comprise a buck converter, a boost converter, a flyback converter and so on. At times, a behavior of the SMPS is checked by a current sense circuit, which detects a current flowing through a switch in the SMPS.

### SUMMARY

In some embodiments of the present disclosure, a current sense circuit for a switching converter is provided. The switching converter includes a first power switch and a second power switch coupled in series with the first power switch. The current sense circuit includes a sensing input terminal, an amplifier circuit, a sensing resistor, and a current-limiting circuit. The sensing input terminal is configured to be coupled to a first terminal of the second power switch to receive a first signal. The amplifier circuit has a first input terminal, a second input terminal, and an output terminal. The first input terminal of the amplifier circuit is coupled to the sensing input terminal to receive the first signal, the second input terminal of the amplifier circuit is coupled to a reference voltage, and the output terminal of the amplifier circuit is configured to provide a current sense signal indicating a current flowing through the second power switch in response to the first signal when the second power switch is turned on. The sensing resistor is coupled between the first input terminal of the amplifier circuit and the output terminal of the amplifier circuit. The current-limiting circuit is coupled in series with the sensing resistor. The current-limiting circuit is configured to limit a current flowing through the sensing resistor when the first power switch is turned on.

In some embodiments of the present disclosure, an integrated circuit includes a sensing input terminal and a current sense circuit. The sensing input terminal is configured to receive a first signal. The current sense circuit is configured to provide a current sense signal. The current sense circuit includes an amplifier circuit and a sensing resistor. The amplifier circuit includes a first input terminal, a second input terminal, an output terminal, a first transistor, and a second transistor. The first input terminal is coupled to the sensing input terminal to receive the first signal. The second input terminal is coupled to a reference voltage. The output terminal is configured to provide the current sense signal. The first transistor is coupled between a power terminal and the output terminal. The second transistor is coupled between the output terminal and a ground terminal. The sensing resistor is coupled between the first input terminal and the output terminal. When the first signal is at a voltage level higher than the reference voltage, the second transistor limits a constant current flowing through the sensing resistor between the first input terminal and the output terminal.

In some embodiments of the present disclosure, a current sense method for controlling a switching converter is provided, in which the switching converter comprises a first power switch and a second power switch coupled in series with the first power switch. The method includes providing an amplifier circuit with a sensing resistor coupled between a first input terminal of the amplifier circuit and an output terminal of the amplifier circuit; receiving a first signal, by a first input terminal of the amplifier circuit; receiving a reference voltage, by a second input terminal of the amplifier circuit; providing a current sense signal indicating a current flowing through the second power switch at the output terminal of the amplifier circuit in response to the first signal when the second power switch is turned on; and limiting a current flowing through the sensing resistor by a current-limiting circuit when the first power switch is turned on.

### BRIEF DESCRIPTION OF THE DRAWINGS

The disclosure can be more fully understood by reading the following detailed description of the embodiment, with reference made to the accompanying drawings as follows.

FIG. 1 is a schematic block diagram of a current sense circuit according to some embodiments of the present disclosure.

FIGS. 2A and 2B are schematic circuit diagrams of a current sense circuit respectively at a first state and a second state of a pulse width modulation (PWM) signal in some comparison cases

FIG. 3 is a circuit diagram of an exemplary two-stage operational amplifier circuit according to some embodiments of the present disclosure.

FIGS. 4A and 4B are schematic circuit diagrams illustrating the working principle of a current sense circuit according to some embodiments of the present disclosure.

FIG. 5A is a schematic circuit diagram of an exemplary two-stage operational amplifier circuit according to an embodiment of the present disclosure.

FIG. 5B is a circuit diagram of an exemplary two-stage operational amplifier circuit according to an embodiment of the present disclosure.

FIG. 6 is a schematic diagram of simulated waveforms of signals with reference to the current sense circuit as shown in FIGS. 4A and 4B according to some embodiments of the present invention.

FIGS. 7A and 7B are schematic circuit diagrams of a current sense circuit respectively at a first state and a second state of a PWM signal according to some embodiments of the present disclosure.

FIG. 8A is a schematic circuit diagram of a current sense circuit at a second state of a PWM signal according to some embodiments of the present disclosure.

FIG. 8B is a circuit diagram of an exemplary two-stage operational amplifier circuit and a current-limit circuit including a current source according to some embodiments of the present disclosure.

FIG. 9 is a schematic circuit diagram of a current sense circuit at a second state of a PWM signal according to some embodiments of the present disclosure.

FIG. 10 is a schematic block diagram of an integrated circuit according to some embodiments of the present disclosure.

FIG. 11 is a flow chart of a method for controlling a switching converter according to some embodiments of the present disclosure.

### DETAILED DESCRIPTION

Embodiments of the present invention will be described in detail below. It should be noted that the embodiments described here are only for illustration and are not intended to limit the present invention. In the following description, numerous specific details are set forth in order to provide a thorough understanding of the invention. However, it will be apparent to one of ordinary skill in the art that these specific details need not be employed in order to practice the invention. In other instances, well-known materials or methods have not been described in detail in order to avoid obscuring the present invention.

Throughout this specification, the phrases “in one embodiment,” “in an embodiment,” “in one example,” or “in one implementation” as used includes both combinations and sub-combinations of various features, structures, or characteristic described herein as well as variations and modifications thereof. These phrases used herein do not necessarily refer to the same embodiment, although it may. Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element, or indirectly connected to or coupled to the other element via another element. Furthermore, particular features, structures, or characteristics may be included in an integrated circuit, an electronic circuit, a combinational logic circuit, or other suitable components that provide the described functionality. Furthermore, those of ordinary skill in the art will appreciate that the drawings provided herein are for illustrative purposes and that the drawings are not necessarily drawn to scale. The same reference numbers indicate the same elements. As used herein, the term “and/or” includes any and all combinations of one or more of the associated listed items.

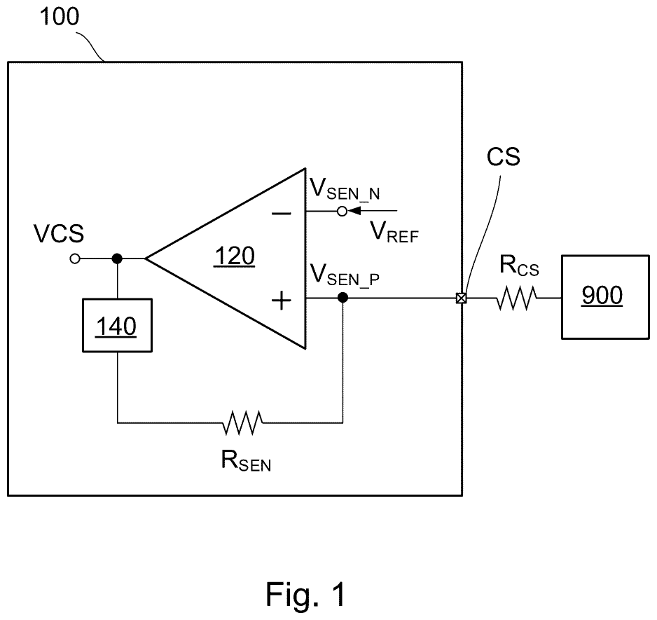

FIG. 1 is a schematic circuit diagram of a current sense circuit 100 according to an embodiment of the present disclosure. The current sense circuit 100 is for a switching converter 900. The current sense circuit 100 includes a sensing input terminal CS, an amplifier circuit 120, a sensing resistor R_{SEN}, and a current-limiting circuit 140. The sensing input terminal CS is configured to be coupled to the switching converter 900 to receive a first signal (e.g. voltage signal). In the illustrated embodiments, a resistor R_{CS} is coupled between the sensing input terminal CS and the switching converter 900. The amplifier circuit 120 has a first input terminal V_{SEN_P}, a second input terminal V_{SEN_N}, and an output terminal VCS. The first input terminal V_{SEN_P} of the amplifier circuit 120 is coupled to the sensing input terminal CS to receive the first signal (e.g. voltage signal). The second input terminal V_{SEN_N} of the amplifier circuit 120 is coupled to a reference voltage V_{REF}. The output terminal VCS of the amplifier circuit 120 is configured to provide a current sense signal indicating a current in the switching converter 900 in response to the first signal. The sensing resistor R_{SEN} is coupled between the first input terminal V_{SEN_P} of the amplifier circuit 120 and the output terminal VCS of the amplifier circuit 120. The current-limiting circuit 140 is coupled in series with the sensing resistor R_{SEN}. The current-limiting circuit 140 is configured to limit a current flowing through the sensing resistor R_{SEN}.

With the configuration of the current-limiting circuit 140, the current flowing through the sensing resistor R_{SEN} can be limited when the current sense is not performed, thereby saving power consumption of the current sense circuit 100.

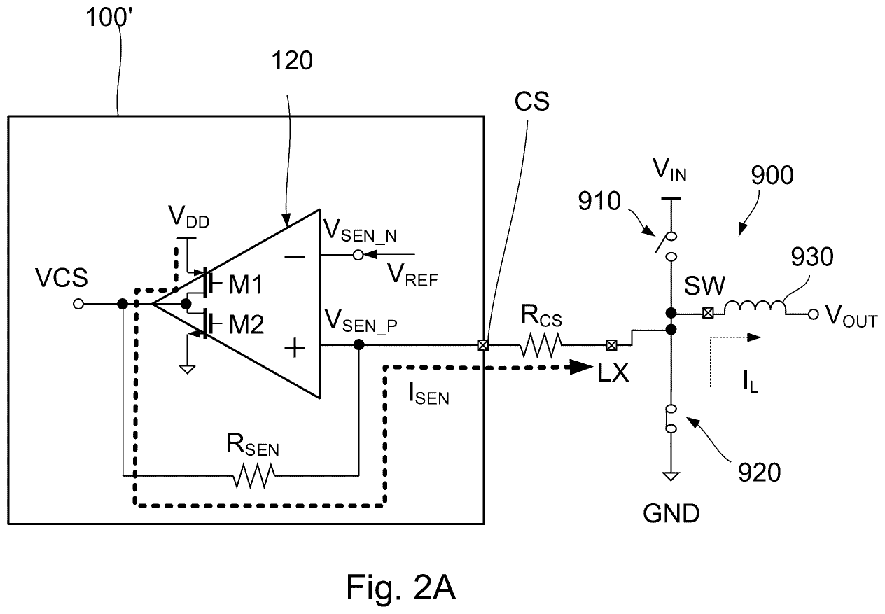

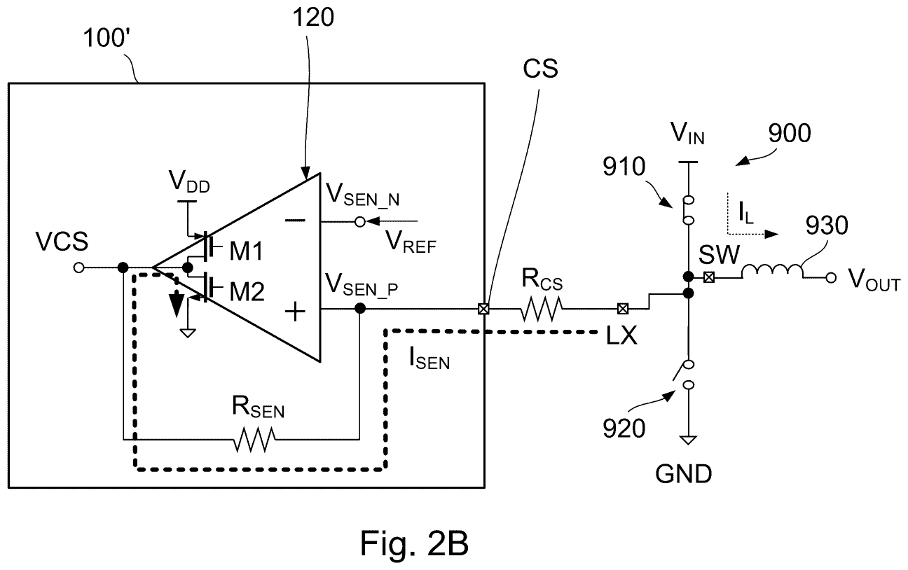

FIGS. 2A and 2B are schematic circuit diagrams illustrating the working principle of a current sense circuit 100′ according to an embodiment of the present disclosure. In one embodiment, the switching converter 900 is a buck converter. However, in another embodiment, the switching converter 900 is a boost converter. In yet another embodiment, the switching converter 900 is a buck-boost converter. In some embodiments, the switching converter 900 is a flyback converter. However, the present disclosure is not limited thereto. In various embodiments, the switching converter 900 may be any types of power converter. The switching converter 900 includes a first power switch 910, a second power switch 920, and an inductor 930. In detail, for the buck converter, the first power switch 910 is coupled between an input node V_{IN} and a switching node SW, the second power switch 920 is coupled between the switching node SW and a ground terminal GND, and the inductor 930 is coupled between the switching node SW and an output node V_{OUT}. The operating principle of the buck converter involves controlling energy transfer from the input node V_{IN} to the output node V_{OUT} through the first power switch 910, the second power switch 920, and the inductor 930. By adjusting the duty cycle of the first power switch 910, the average output voltage may be regulated proportionally to the input voltage. When the first power switch 910 of the switching converter 900 is switched on, it allows current to flow through the inductor 930, which stores energy in its magnetic field. This stored energy is then transferred to the output node V_{OUT}, charging an output capacitor and powering an output load. When the first power switch 910 is turned off and the second power switch 920 is turned on, the magnetic field of the inductor 930 collapses, releasing the stored energy and maintaining the current flow to the output load. In one embodiment, the first power switch 910 and the second power switch 920 each include a transistor, for example, a Metal Oxide Semiconductor Field Effect Transistor (MOSFET). Each of the first power switch 910 and the second power switch 920 has first and second terminals (e.g., source and drain) and a control terminal (e.g., gate) configured to control a conduction between the first and second terminals or not. The first power switch 910 and the second power switch 920 are controlled by the PWM signal. For example, as shown in FIG. 2A, when the PWM signal is at the second state (e.g., a low logic level), the first power switch 910 is turned off, and the second power switch 920 is turned on. On the other hand; as shown in FIG. 2B, when the PWM signal being at the first state (e.g., a high logic level), when the first power switch 910 is turned on, and the second power switch 920 is turned off.

In some embodiments, the current sense circuit 100 senses the current flowing through the low-side switch (i.e., the second power switch 920). That is, the sensing input terminal CS of the current sense circuit 100 is configured to be coupled to a node LX, (i.e., a first terminal of the second power switch 920), to receive the first signal. The output terminal VCS of the amplifier circuit 120 is configured to provide a current sense signal indicating the current I_{L} flowing through the second power switch 920 in response to the first signal received by the sensing input terminal CS.

In the shown embodiment, the amplifier circuit 120 includes an output stage circuit. The output stage circuit includes a first transistor M1 coupled between a power terminal V_{DD} and the output terminal VCS and a second transistor M2 coupled between the output terminal VCS and a ground terminal. The amplifier circuit 120 can be a two-stage amplifier, a three-stage amplifier, a four-stage amplifier, or any other suitable circuits.

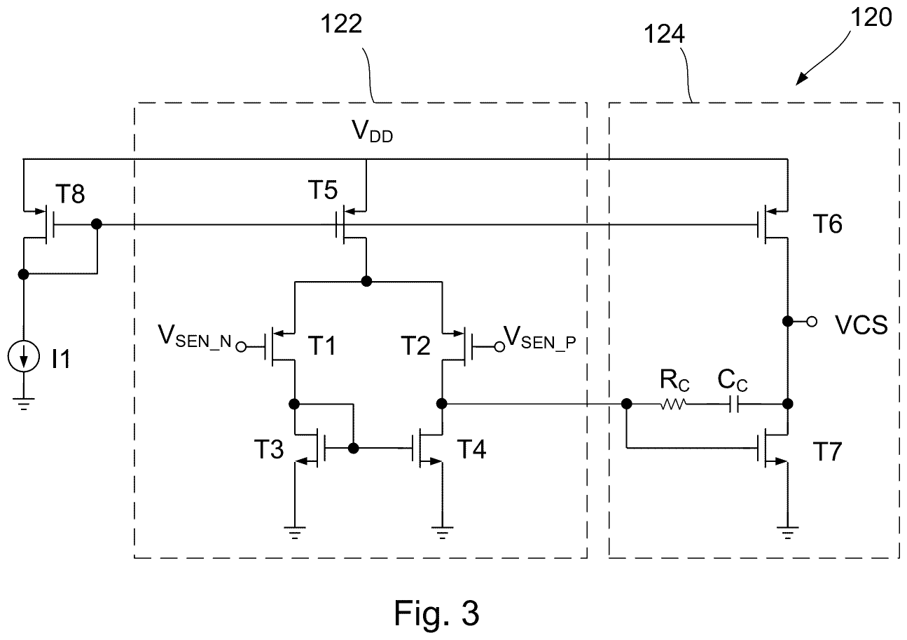

FIG. 3 is a circuit diagram of an exemplary two-stage operational amplifier circuit 120 according to some embodiments of the present disclosure. The amplifier circuit 120 may include an input stage circuit 122 coupled to the first and the second input terminals V_{SEN_P} and V_{SEN_N} and an output stage circuit 124 coupled to the input stage circuit 122. Transistors T6 and T7 of the output stage circuit 124 in the embodiments of FIG. 3 may serve as the transistors M1 and M2 of FIGS. 2A and 2B. In the illustrated embodiments, the input stage circuit 122 is defined by a differential input and single-ended output, and the output stage circuit 124 serves as a common-source amplifier.

The input stage circuit 122 may include transistors T1-T5. The transistors T1 and T2 form a differential pair to receive the first signal and a reference voltage V_{REF}. A current source 11 providing a control current is coupled in series with the transistor T8. The transistor T5 form a current mirror with the transistor M8, thereby mirroring the control current, thereby supplying the differential pair of the transistors T1 and T2 with a bias current. The transistors T3 and T4 form a current mirror to fix the bias currents flowing through the transistors T1 and T2.

Serving as the common-source amplifier, the output stage circuit 124 includes the transistor T7 and actively loaded with the transistor T6. The gate of the transistor T7 is coupled to the output terminal of the input stage circuit 122. The transistor T6 form a current mirror with the transistor T8, thereby mirroring the control current provided by the current source 11, thereby supplying the transistor T7 with a bias current.

In one embodiment, the amplifier circuit 120 include a compensation circuit (e.g., a compensation capacitor C_{C} and a compensation resistor R_{C}). Specifically, the compensation capacitor C_{C} and the compensation resistor R_{C} are coupled between the output terminal of the input stage circuit 122 and the drain terminal of the transistor T7 for improving the frequency compensation.

Reference is made back to FIGS. 2A and 2B. When the second power switch 920 is turned on and the first power switch 910 is turned off as shown in FIG. 2A, the current I_{L} flows from the ground terminal GND to the output node V_{OUT} through the second power switch 920 and the inductor 930. The node LX is at a low voltage level, and a current I_{SEN} flows from the power terminal V_{DD} through the first transistor M1, the sensing resistor R_{SEN}, and the resistor R_{CS} to the node LX. As a result, the voltage at the node LX can be represented as below:

LX=0−I_{L}×R_{LSON} (1),

where R_{LSON} is an on-resistance of the second power switch 920.

Since the voltage at the first input terminal V_{SEN_P} is equal to the reference voltage V_{REF} at the second input terminal V_{SEN_N}, the voltage at the output terminal VCS can be represented as below:

$$VCS = {I}_{SEN} \times {R}_{SEN} + {V}_{REF} = ( {V}_{REF} - LX ) \times \frac{{R}_{SEN}}{{R}_{CS}} + {V}_{REF} = {V}_{CNT} - LX \times \frac{{R}_{SEN}}{{R}_{CS}} , \qquad ( 2 )$$

where V_{CNT} is a constant voltage value.

With the equations (1) and (2), the voltage at the output terminal VCS can be represented as below:

$$VCS = {V}_{CNT} + {I}_{L} \times \frac{{R}_{LSON} \times {R}_{SEN}}{{R}_{CS}} .$$

From equation (3), the voltage at the output terminal VCS represents the information of the current I_{L}, thereby performing current sense. In other words, the voltage at the output terminal VCS is defined by the resistance of the resistor R_{CS} and the resistance of the sensing resistor R_{SEN}. Also, the current sensing range may be well-controlled by the resistor R_{CS} and the sensing resistor R_{SEN}.

On the other hand, when the first power switch 910 is turned on, and the second power switch 920 is turned off as shown in FIG. 2B, the current I_{L} flows from the input node V_{IN} to the output node V_{OUT} through the first power switch 910 and the inductor 930. In this case, the node LX is at a high voltage level (e.g., LX=V_{IN}), and thus the current I_{SEN} flows from the node LX through the resistor R_{CS}, the sensing resistor R_{SEN}, and the second transistor M2, to the ground terminal. At this state, the current sense circuit 100′ does not perform current sense.

However, since the voltage at the first input terminal V_{SEN_P} is equal to the reference voltage V_{REF} at the second input terminal V_{SEN_N}, the current I_{SEN} flowing through the resistor R_{CS} and the sensing resistor R_{SEN} would be large (e.g., greater than 5 mA), which may cause poor power consumption. Furthermore, sometimes, the voltage at the first input terminal V_{SEN_P} may increase to the voltage at the node LX, which may be almost equal to the high voltage at the input node V_{IN}. The high voltage at the first input terminal V_{SEN_P} may damage the circuit. One way is to disable the current sense circuit 100′ when the first power switch 910 is turned on. However, long settling time is need for turning on the current sense circuit 100′ again. Therefore, in present disclosure, a current-limiting circuit is provided to limit a current flowing through the sensing resistor when the first power switch is turned on.

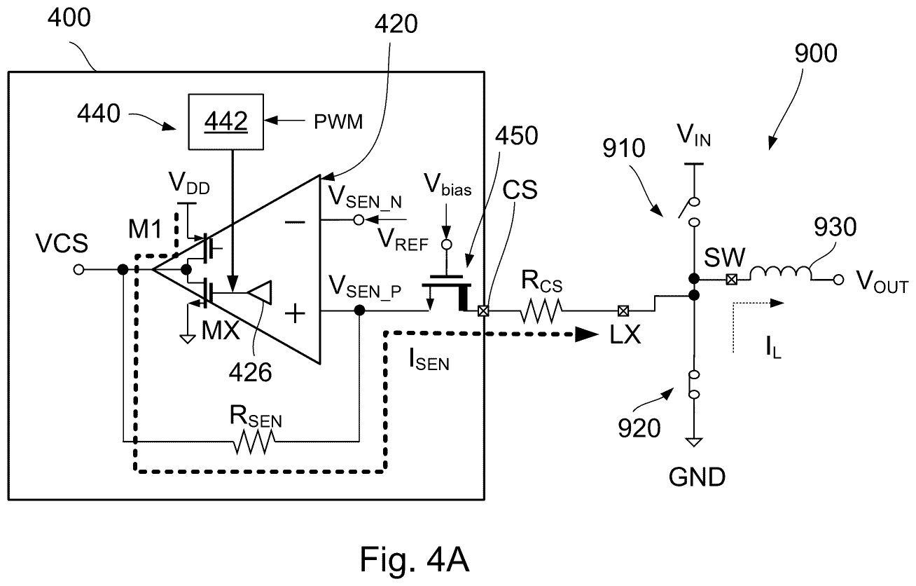

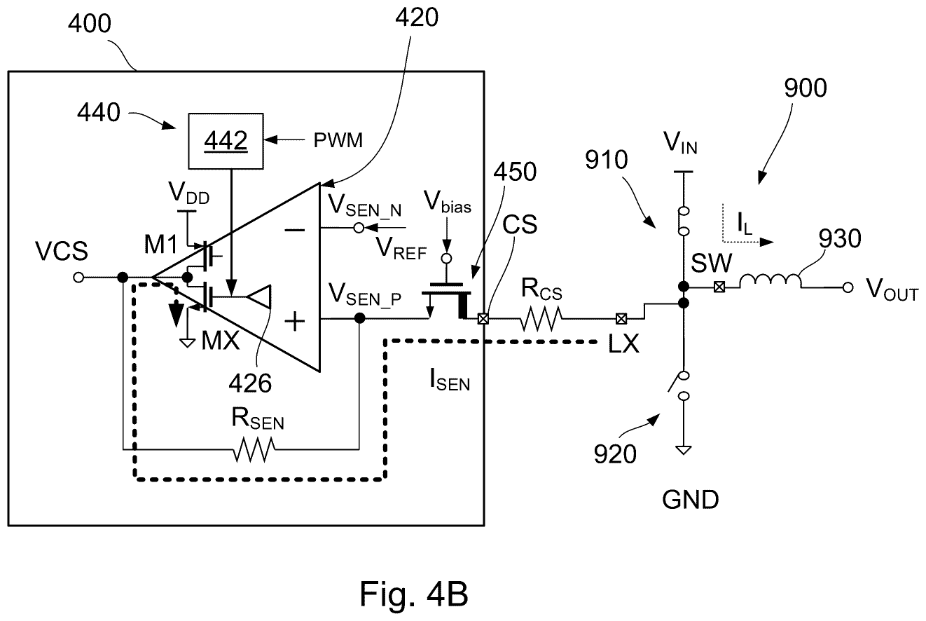

FIGS. 4A and 4B are schematic circuit diagrams illustrating the working principle of a current sense circuit 400 according to some embodiments of the present disclosure. The current sense circuit 400 includes a sensing input terminal CS, an amplifier circuit 420, a sensing resistor R_{SEN}, and a current-limiting circuit 440. In one embodiment as shown in FIG. 4A, the current-limiting circuit 440 includes a transistor MX and a clamping circuit 442. The transistor MX is coupled between the output terminal VCS and the ground terminal. For example, the transistor MX is coupled between the transistor M1 of the amplifier circuit 420 and the ground terminal. The clamping circuit 442 is configured to clamp a voltage of a control terminal of the transistor MX when the first power switch 910 is turned on. The clamping circuit 442 may be any suitable circuit having a holding and an outputting function. In some embodiments, the clamping circuit 442 is a circuit that provides a maximum DC level limitation, thereby clamping the transistor MX. For example, the clamping circuit 442 may receive the PWM signal, and provide the DC voltage to limit the maximum voltage at the gate terminal of the transistor MX to clamp the transistor MX. The clamping circuit 442 may include a transistor, a capacitor, a diode, a resistor, other suitable component, and the combination thereof. In one implementation, the control terminal of the transistor MX is configured to receive a signal from other circuits of the amplifier circuit 420 (e.g., the input stage circuit). For instance, a buffer circuit 426 represents the circuit of the amplifier circuit 420 that is coupled to the control terminal of the transistor MX.

As shown in FIG. 4A, when the PWM signal is at the low logic level such that the second power switch 920 is turned on and the first power switch 910 is turned off, the clamping circuit 440 does not clamp a voltage of the control terminal of the transistor MX. Due to the high input impedance of the operational amplifier, the voltage at the first input terminal V_{SEN_P} is approximately equal to the voltage (i.e., the reference voltage V_{REF}) at the second input terminal V_{SEN_N}. For instance, the reference voltage V_{REF} is 30 mV, the voltage at the first input terminal V_{SEN_P} is about 30 mV, and the voltage at the node LX is-100 mV. Therefore, the current I_{SEN} flows from the power terminal V_{DD} through the sensing resistor R_{SEN} and the resistor R_{CS} to the node LX. As a result, the current sense circuit 400 senses the first signal at the sensing input terminal CS, and provide a current sense signal at the output terminal VCS indicating the current I_{L} flowing through the second power switch 920, thereby performing current sense.

As shown in FIG. 4B, when the PWM signal is at the high logic level such that the first power switch 910 is turned on and the second power switch 910 is turned off, the clamping circuit 442 clamps a voltage of the control terminal of the transistor MX. Since the first power switch 910 is turned on, the node LX is at a high voltage level approximately the voltage at the input node V_{IN}, and thus the voltage at the sensing input terminal CS is at a higher voltage level. For instance, when the voltage at the input node V_{IN} is 12V, the voltage at the node LX is approximately 12V, which is higher than the voltage at the first input terminal V_{SEN_P}. Accordingly, the current I_{SEN} flows from the node LX through the resistor R_{CS}, the sensing resistor R_{SEN}, and the transistor MX to the ground terminal. The control terminal of the transistor MX is clamped, thereby limiting the current I_{SEN} flowing through the transistor MX.

In some embodiments, the current sense circuit 400 further includes a switch device 450 coupled between the sensing input terminal CS and the first input terminal V_{SEN_P} of the amplifier circuit 420. The switch device 450 is configured to provide a conduction path between the sensing input terminal CS and the first input terminal V_{SEN_P} and withstand a high voltage difference therebetween. With the switch device 450, while the current I_{SEN} flows from the sensing input terminal CS to the first input terminal V_{SEN_P}, the high voltage from the sensing input terminal CS is prevented from passing to the first input terminal V_{SEN_P} and damaging circuits. In some embodiments, the switch device 450 is a MOSFET having a drain-to-source breakdown voltage greater than the voltage at the input node V_{IN} (e.g., 12V). For example, the switch device 450 may be a lateral double diffused MOS (LDMOS). In some embodiments, a bias voltage V_{bias} (e.g., 5V) is applied to the control terminal of the switch device 450 for turning on and biasing the switch device 450. For instance, when the first power switch 910 is turned on, as the voltage at the input node V_{IN} is 12V, the voltage at the node LX is approximately 12V, and the switch device 450 can withstand 12V and keep the voltage at the first input terminal V_{SEN_P} at about 5V.

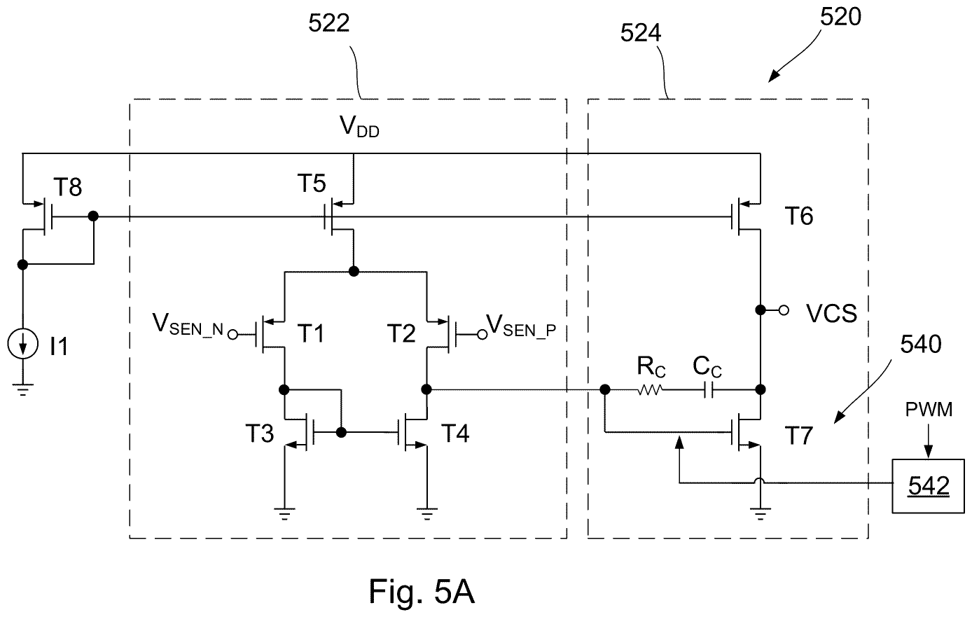

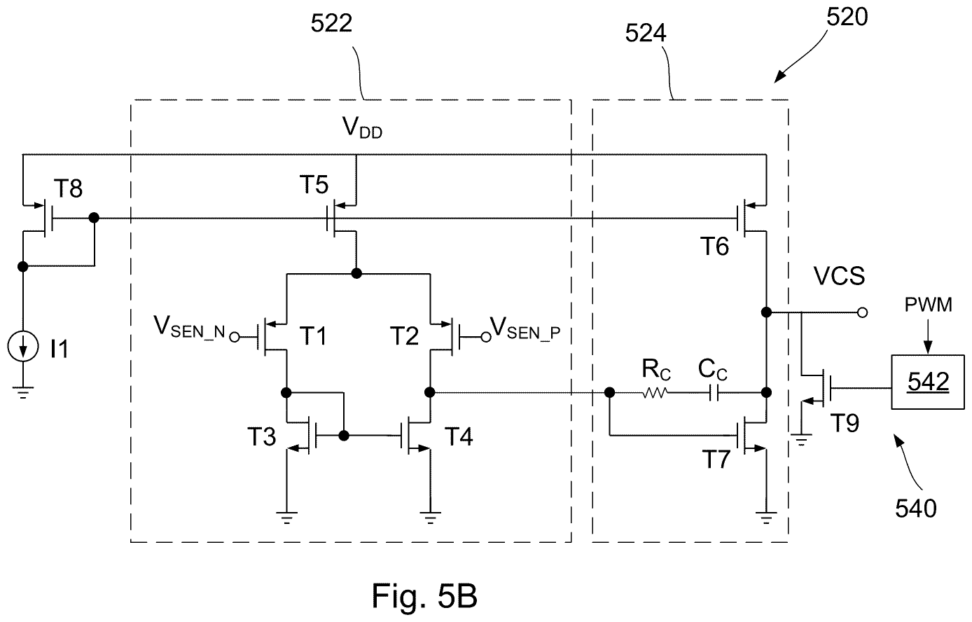

FIG. 5A is a schematic circuit diagram of an exemplary two-stage operational amplifier circuit according to an embodiment of the present disclosure. The amplifier circuit 520 may include an input stage 822 and an output stage 824. In the present embodiment, the current-limit circuit 540 includes a transistor T7 and a clamping circuit 542 configured to clamp a voltage of a control terminal of the transistor T7 according to the PWM signal or not. In the present embodiment, the transistor T7 is a component at the output stage 124 of the amplifier circuit 520 for providing the current sense signal at the output terminal VCS. Other details of the present embodiments are similar to those illustrated previously, and thereto not repeated herein.

FIG. 5B is a schematic circuit diagram of an exemplary two-stage operational amplifier circuit according to another embodiment of the present disclosure. In this embodiment, the current-limit circuit 540 includes the transistor T9 and the clamping circuit 542 configured to clamp a voltage of a control terminal of the transistor T9 according to the PWM signal or not. In the present embodiment, the transistor T9 is an additional transistor coupled between the output terminal VCS and the ground terminal, for example, being external to the amplifier circuit 520. Other details of the present embodiments are similar to those illustrated previously, and thereto not repeated herein.

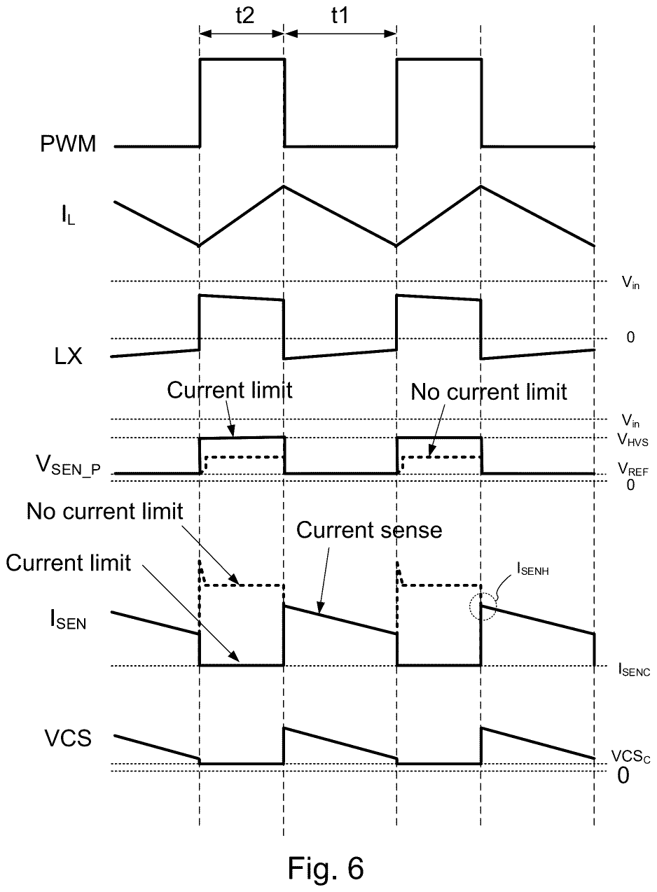

FIG. 6 is a schematic diagram of simulated waveforms of signals of the current sense circuit 400 as shown in FIGS. 4A and 4B according to some embodiments of the present invention. When the second power switch 920 is turned on during the time period t1, the PWM signal is at the low logic level. The current sense circuit performs the current sense function. At the same time, the voltage at the node LX is at a low voltage level, and the current I_{SEN} is proportional to the inductor current I_{L}, and the voltage at the output terminal VCS represents the inductor current I_{L}.

When the first power switch 910 is turned on during the time period t2, the PWM signal is at the high logic level, the current sense circuit does not perform the current sense function. Meanwhile, the current-limiting circuit limits the current flowing through the sensing resistor. For example, when the voltage at the node LX is at a high voltage level, the current I_{SEN} is limited to a constant value I_{SENC}. At this stage, the voltage at the output terminal VCS may be limited to a constant value VCS_{C}. In some alternative embodiments, the current I_{SEN} and the voltage at the output terminal VCS being limited may have other signal profile (e.g., having a small slope), rather than being constant.

Without the current-limiting circuit, when the PWM signal transitions to the high logic level, the current I_{SEN} would be extremely large (as denoted by the bold dashed line) since the voltage at the first input terminal V_{SEN_P} is equal to the reference voltage V_{REF}. This large current would cause poor power consumption and may damage the circuit.

As shown in FIG. 6, with the current-limiting circuit, the current I_{SEN} would be kept low at a constant value I_{SENC}, as shown by the bold solid line, which is lower than the voltage level indicated by the bold dashed line, thereby saving power consumption. In some examples, the current I_{SEN} during the time period t2 is kept at a level (e.g., the constant value I_{SENC}) lower than the maximum I_{SENH} of the current I_{SEN} during the time period t1 when the PWM signal is at the low logic level. In the shown embodiments, the current I_{SEN} during the time period t2 (e.g., the constant value I_{SENC}) is less than the minimum of the current I_{SEN} during the time period t1. In some alternative embodiments, the current I_{SEN} during the time period t2 can be equal to or greater than the minimum of the current I_{SEN} during the time period t1.

On the other hand, during the time period t2 when the PWM signal is at a high logic level, the voltage at the first input terminal V_{SEN_P} might go as high as to the voltage at the switching node LX, as shown by the bold dashed line. In some embodiments of the present disclosure, with the switch device 450 (referring to FIGS. 4A and 4B), during the time period t2, the voltage at the first input terminal V_{SEN_P} is kept at a voltage level V_{HVS} higher than the voltage level indicated by the bold dashed line, and lower than the voltages at the switching node LX (e.g., the voltage at the input node Vin). Thus, the switch device 450 (referring to FIGS. 4A and 4B) may protect the circuit from being damaged.

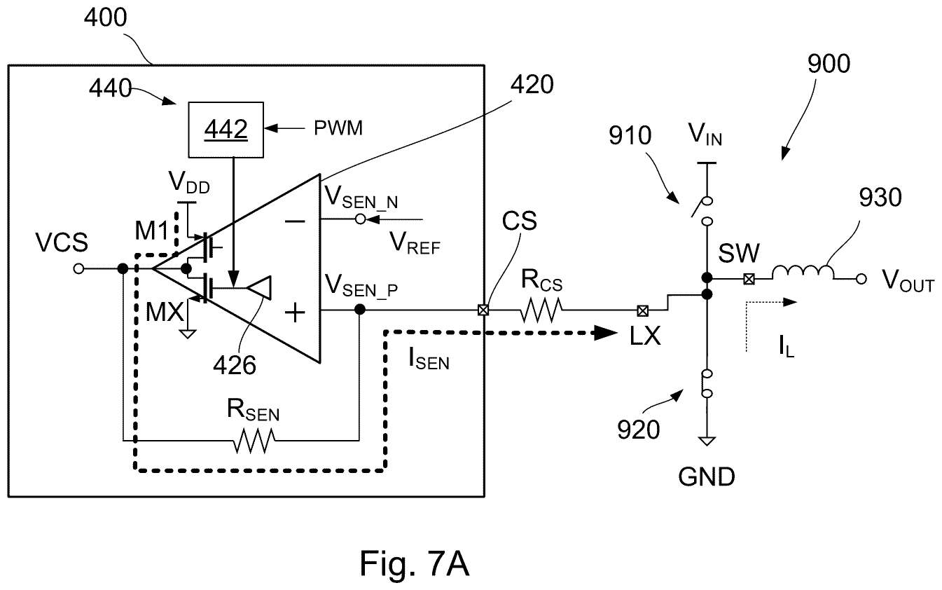

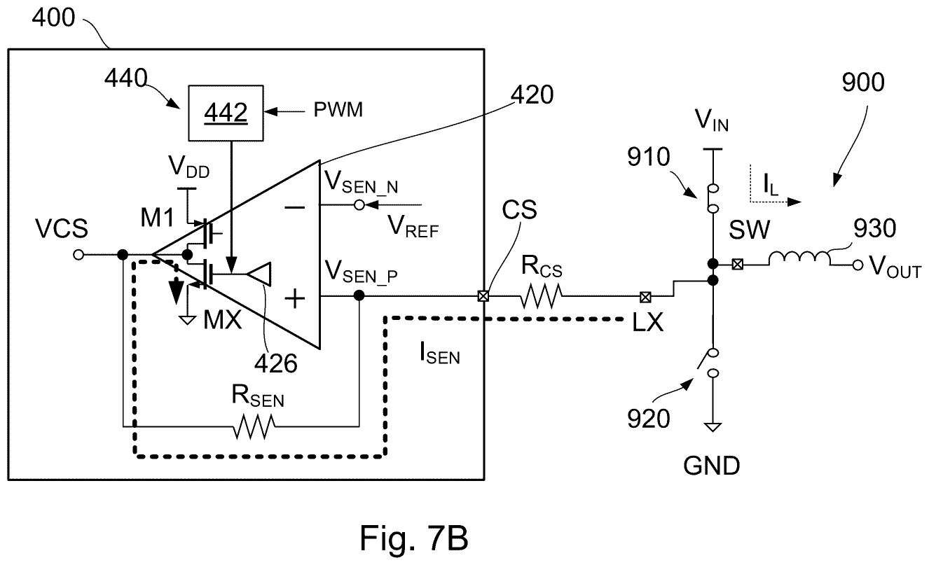

FIGS. 7A and 7B are schematic circuit diagrams of a current sense circuit respectively at a first state (e.g., low logic level) and a second state (e.g., high logic level) of a PWM signal according to some embodiments of the present disclosure. Details of the present embodiments are similar to those illustrated in the embodiments of FIGS. 4A and 4B, except that the switch device 140 is omitted in the present embodiments. Other details of the present embodiments are similar to those illustrated in embodiments of FIGS. 4A and 4B, and thereto not repeated herein.

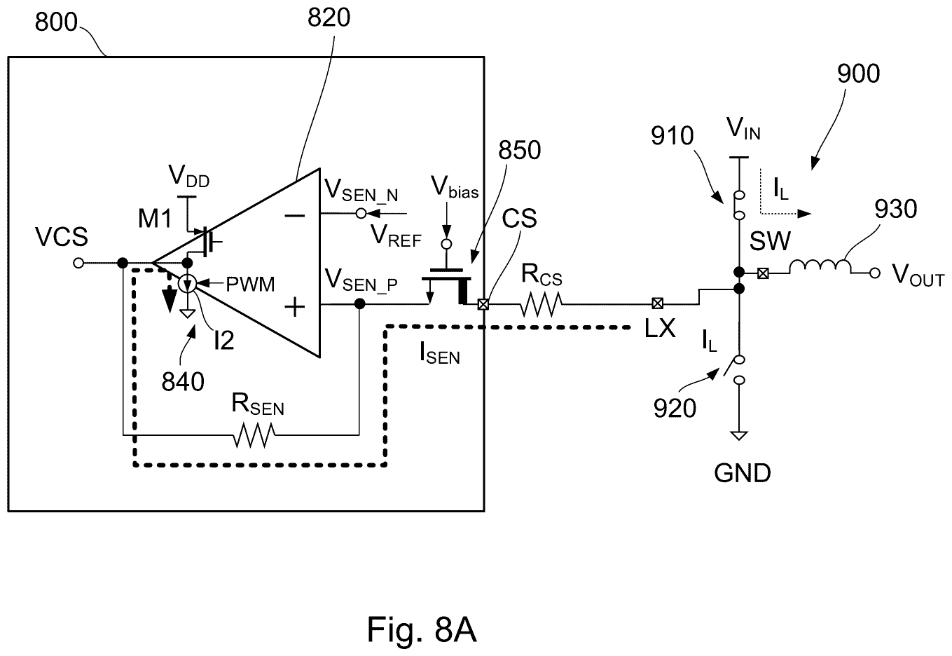

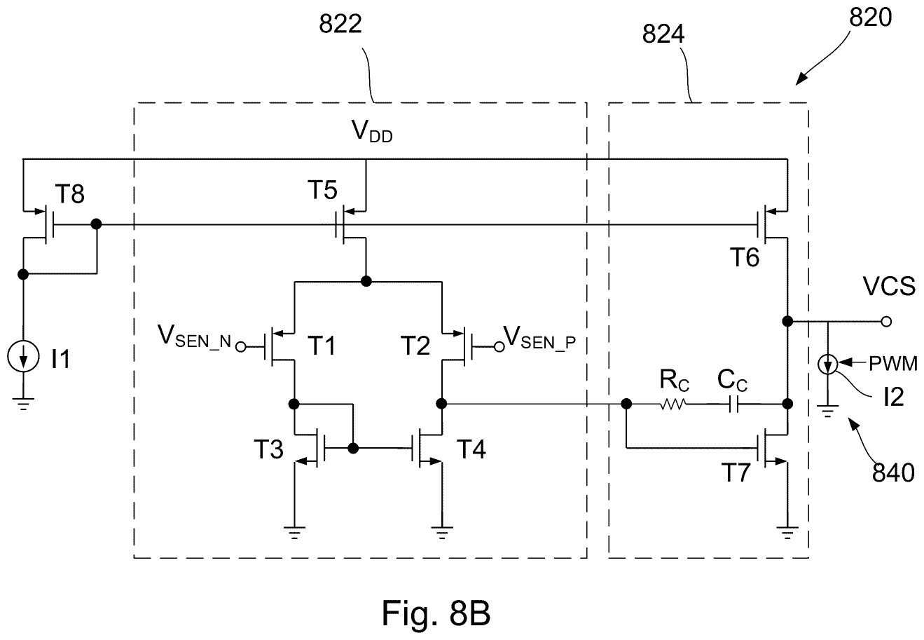

FIG. 8A is a schematic circuit diagram of a current sense circuit 800 at a second state of a PWM signal according to some embodiments of the present disclosure. The current sense circuit 800 includes a sensing input terminal CS, an amplifier circuit 820, a sensing resistor R_{SEN}, a current-limiting circuit 840, and a switch device 850. Details of the present embodiments are similar to those illustrated in the embodiments of FIG. 4B, except that the current-limiting circuit 840 in the current sense circuit 800 includes a current source 12 coupled to the output terminal VCS. The current source 12 is configured to provide a current when the first power switch 910 is turned on, in which the current provided by the current source 12 flows through the sensing resistor R_{SEN}. In some embodiments, the current source 12 is configured to provide the constant current when the first signal received by the sensing input terminal CS is at the voltage level higher than the reference voltage V_{REF}.

FIG. 8B is a circuit diagram of an exemplary two-stage operational amplifier circuit 820 and a current-limit circuit 840 including the current source 12 according to some embodiments of the present disclosure. With reference to both FIGS. 8A and 8B. While the amplifier circuit 820 includes the input stage 822 and the output stage 824, the current source 12 can be coupled to the terminals of the transistors T6 and T7 of the output stage 824. The transistor T6 of the output stage circuit 824 may serve as the transistor M1 of FIG. 8A. Other details of the present embodiments are similar to those illustrated previously, and thereto not repeated herein.

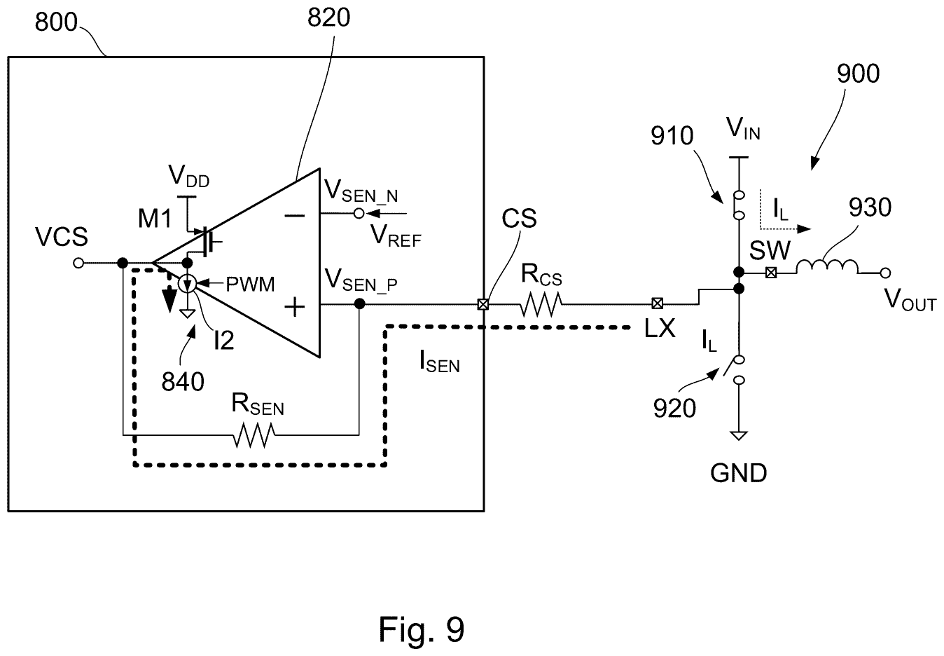

FIG. 9 is a schematic circuit diagram of a current sense circuit at a second state according to some embodiments of the present disclosure. Details of the present embodiments are similar to those illustrated in the embodiments of FIG. 8A, except that the switch device 850 is omitted in the present embodiments. Other details of the present embodiments are similar to those illustrated in embodiments of FIG. 8A, and thereto not repeated herein.

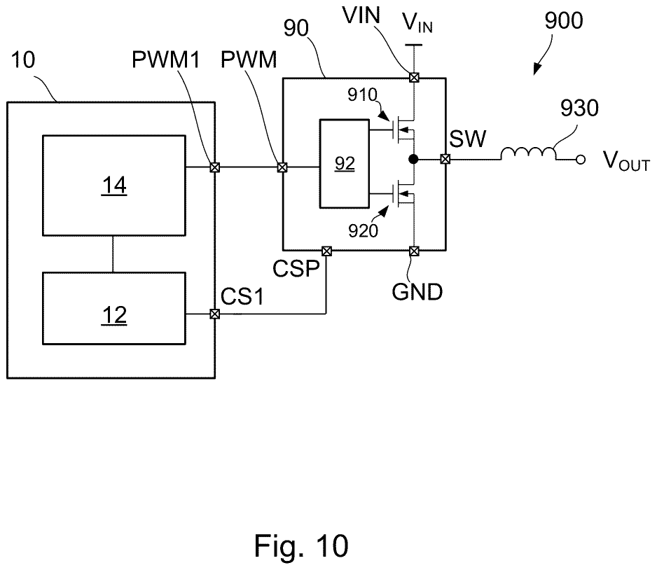

FIG. 10 is a schematic block diagram of a control circuit for a switching converter 900 according to some embodiments of the present disclosure. In one embodiment, the control circuit is an integrated circuit 10 including a current sense circuit 12 and a switching control circuit 14. As aforementioned, the current sense circuit 12 is configured to sense the low side current flowing the power switch 920 when the power switch 910 is turned off and limit the current entering itself when the power switch 910 is turned on. The current sense circuit 12 can be the current sense circuit 400 (referring to FIGS. 4A, 4B, 7A, 7B), the current sense circuit 800 (referring to FIGS. 8A, 9), or the like. The switching control circuit 14 is configured to generate a control signal (e.g., the PWM signal) to control the power switches 910 and 920 of the switching converter 900.

In some embodiments, the integrated circuit 10 may be a controller IC. The switch converter 900 includes a power stage circuit 90 and the inductor 930. In one embodiment, the power stage circuit 90 is an IC. The controller IC 10 has a switching control pin PWM1 configured to send a control signal to the power stage circuit 90 and a current sense pin CS1 configured to receive a voltage signal from the power stage circuit 90 indicating a low side current flowing the power switch 920 and the inductor 930. The power stage circuit 90 includes an input pin VIN, a switch pin SW, and a switching control pin PWM. The input pin VIN is configured to be coupled to the input node V_{IN}. The switching control pin SW is configured to provide the output voltage via the inductor 930 at the output node V_{OUT}. The switching control pin PWM is configured to receive the control signal from the switching control pin PWM1 of the controller IC 10. In the illustrated embodiments, the power stage circuit 90 includes the current sense pin CS configured to report the low-side current to the current sense pin CS1 of the controller IC 10, e.g. through current sense circuits inside the power stage circuit 90 (not shown). In some alternative embodiments, the current sense pin CS1 of the controller IC 10 is coupled to the switch pin SW for receiving the voltage signal indicating the low side current flowing the power switch 920 and the inductor 930 through external circuits. The power stage circuit 90 may further include a driving control circuit 92 configured to provide the driving signals to the control terminals of the power switches 910 and 920 according to the control signal received from the switching control pin PWM. In furtherance of some embodiments, the integrated circuit 10 is a multiphase controller integrated circuit (IC) having plural switching control pins, respectively coupled to switching control pins of plural power stage circuits, and plural current sense pins respectively coupled to the current sense pin CS of the power stage circuits. Thus, the switching control circuit 14 controls the power switches 910 and 920 in the plural power stage circuits, and the current sense circuit 12 can sense the low side currents flowing the power switches 920 in the plural power stage circuits and limit the currents entering themselves when the power switches 910 are turned on.

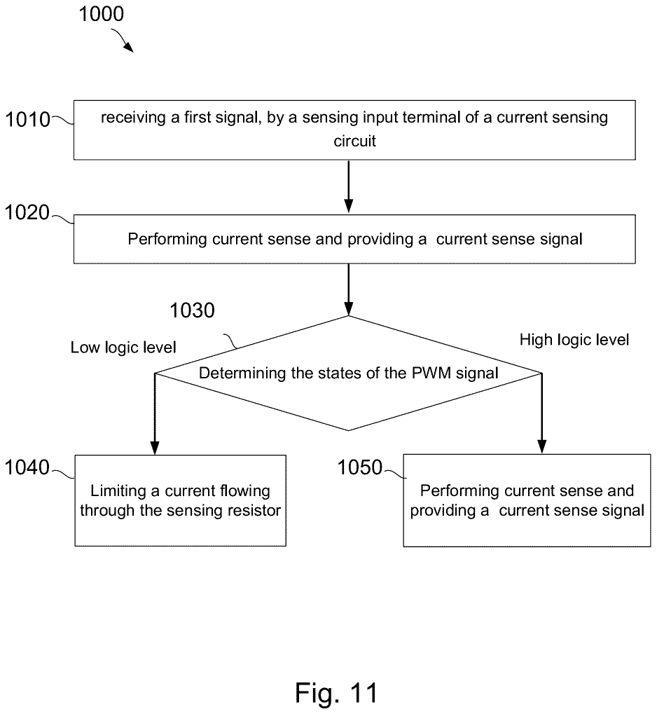

FIG. 11 is a flow chart of a method 1000 for controlling a switching converter according to some embodiments of the present disclosure. The method 1000 may be performed by a current sense circuit as shown in FIGS. 1, 4A and 4B, 7A and 7B, 8A, and 9. The method 1000 includes actions 1010-1050. It is understood that additional actions may be provided before, during, and after the actions 1010-1050 shown in FIG. 11, and some of the actions 1010-1050 described below can be replaced or eliminated for additional embodiments of the method. The order of the operations/processes may be interchangeable. Although the flowchart of FIG. 11 shows a sequential action. It is obvious to persons skilled the art that these actions could be performed in any order.

In action 1010, the current sensing circuit receives a first signal via the sensing input terminal CS.

In action 1020, a current sense signal is provided at the output terminal VCS according to the first signal and the reference voltage V_{REF}.

In action 1030, a determination is made to determine the PWM signal is at a high logic level or a low logic level.

When the PWM signal is at a high logic level, the method 1000 proceeds to action 1040, where a current limiting function is performed.

When the PWM signal is at a low logic level, the method 1000 proceeds to action 1050, where a current sense function is performed, and a current sense signal at the output terminal VCS is provided according to the first signal and the reference voltage V_{REF}.

According to some embodiments of the present disclosure, a current sense circuit is designed with a current-limiting circuit for addressing the issues of the poor power consumption. The current-limiting circuit may include a clamped transistor, a current source, or other components coupled to the output terminal of the current sense circuit. Furthermore, the current sense circuit may include a switch device for withstanding a high voltage from the sensing terminal, thereby addressing the issues of the device damage.

It should be understood that, the circuit and the related components, circuit structures, signals, and waveforms described or shown above in the present disclosure are only for illustration purpose. However, the present disclosure is not limited thereto. Persons having ordinary skill in the art may understood that the control circuit of the present disclosure could be realized, according to practical applications, by any other circuits with different circuit structures, and thus controlled by different types of the corresponding signals to achieve the corresponding functions. For example, the compensation circuit, the ramp generation circuit, the comparison circuit and the logic circuit could be realized by a digital circuit, an analog circuit, a software, an automatic generation circuit by hardware description language, or a combination of the above.

Although the present invention has been described with reference to several exemplary embodiments, it is to be understood that the terms used are illustrative and exemplary rather than restrictive terms. Since the present invention can be embodied in various forms without departing from the spirit or substance of the invention, it should be understood that the above-described embodiments are not limited to any foregoing details, but are to be construed broadly within the spirit and scope defined by the appended claims. Therefore, all changes and modifications falling within the scope of the claims or their equivalents shall be covered by the appended claims.

What is claimed is:

1. A current sense circuit for a switching converter, wherein the switching converter comprises a first power switch and a second power switch coupled in series with the first power switch, the current sense circuit comprising:
a sensing input terminal configured to be coupled to a first terminal of the second power switch to receive a first signal;
an amplifier circuit having a first input terminal, a second input terminal, and an output terminal, wherein the first input terminal of the amplifier circuit is coupled to the sensing input terminal to receive the first signal, the second input terminal of the amplifier circuit is coupled to a reference voltage, and the output terminal of the amplifier circuit is configured to provide a current sense signal indicating a current flowing through the second power switch in response to the first signal when the second power switch is turned on;
a sensing resistor coupled between the first input terminal of the amplifier circuit and the output terminal of the amplifier circuit; and
a current-limiting circuit coupled in series with the sensing resistor, wherein the current-limiting circuit is configured to limit a current flowing through the sensing resistor when the first power switch is turned on.

2. The current sense circuit of claim 1, wherein the amplifier circuit comprises:
an input stage circuit coupled to the first and the second input terminals; and
an output stage circuit coupled to the input stage circuit, wherein the output stage comprises a first transistor coupled between a power terminal and the output terminal of the amplifier circuit and the current-limiting circuit coupled between the output terminal of the amplifier circuit and a ground terminal.

3. The current sense circuit of claim 2, wherein the current-limiting circuit comprises:
a second transistor coupled between the first transistor and the ground terminal; and
a clamping circuit configured to clamp a voltage of a control terminal of the second transistor when the first power switch is turned on.

4. The current sense circuit of claim 2, wherein the current-limiting element comprises:
a current source coupled between the first transistor and the ground terminal, wherein the current source is configured to provide a current when the first power switch is turned on, wherein the current provided by the current source flows through the sensing resistor.

5. The current sense circuit of claim 1, wherein the first signal is at a voltage level higher than the reference voltage when the first power switch is turned on.

6. The current sense circuit of claim 1, further comprising:
a switch device coupled between the sensing input terminal and the first input terminal of the amplifier circuit.

7. An integrated circuit, comprising:
a sensing input terminal configured to receive a first signal; and
a current sense circuit configured to provide a current sense signal, wherein the current sense circuit comprises:
an amplifier circuit comprising:
a first input terminal coupled to the sensing input terminal to receive the first signal;
a second input terminal coupled to a reference voltage;
an output terminal configured to provide the current sense signal;
a first transistor coupled between a power terminal and the output terminal; and
a second transistor coupled between the output terminal and a ground terminal; and
a sensing resistor coupled between the first input terminal and the output terminal, wherein when the first signal is at a voltage level higher than the reference voltage, the second transistor limits a constant current flowing through the sensing resistor between the first input terminal and the output terminal.

8. The integrated circuit of claim 7, further comprising a clamping circuit configured to clamp a voltage of a control terminal of the second transistor when the first signal is at the voltage level higher than the reference voltage.

9. The integrated circuit of claim 7, wherein the second transistor forms a current source configured to provide the constant current when the first signal is at the voltage level higher than the reference voltage.

10. The integrated circuit of claim 7, further comprising:
a switch device coupled between the sensing input terminal and the first input terminal of the amplifier circuit.

11. The integrated circuit of claim 10, wherein the switch device is turned on both when the first signal is at the voltage level higher than the reference voltage and when the first signal is at a level lower than the reference voltage.

12. The integrated circuit of claim 7, wherein when the first signal is at a level lower than the reference voltage, the second transistor does not limit a current flowing through the sensing resistor between the first input terminal and the output terminal.

13. The integrated circuit of claim 7, wherein the integrated circuit is configured to control a switching converter having at least a power switch, and the integrated circuit further comprises:
a switching control circuit configured to generate a control signal to control the power switch, wherein when the control signal is at a first state, the power switch is turned on, and the first signal is at a voltage level higher than the reference voltage.

14. The integrated circuit of claim 13, wherein when the control signal is at a second state, the power switch is turned off, and the first signal is a level lower than the reference voltage.

15. The integrated circuit of claim 8, wherein the current sense circuit further comprises at least one stage circuit of an amplifier circuit coupled among the first input terminal, the second input terminal, a control terminal of the first transistor, and a control terminal of the second transistor.

16. A method for controlling a switching converter, wherein the switching converter comprises a first power switch and a second power switch coupled in series with the first power switch, the method comprising:
providing an amplifier circuit with a sensing resistor coupled between a first input terminal of the amplifier circuit and an output terminal of the amplifier circuit;
receiving a first signal, by a first input terminal of the amplifier circuit;
receiving a reference voltage, by a second input terminal of the amplifier circuit;
providing a current sense signal indicating a current flowing through the second power switch at the output terminal of the amplifier circuit in response to the first signal when the second power switch is turned on; and
limiting a current flowing through the sensing resistor by a current-limiting circuit when the first power switch is turned on.

17. The current sense method of claim 16, further comprises:
providing a transistor coupled between the output terminal of the amplifier circuit and a ground terminal; and
clamping a voltage of a control terminal of the transistor of the amplifier circuit when the first power switch is turned on.

18. The current sense method of claim 16, further comprises:
providing a current source coupled between the output terminal of the amplifier circuit and a ground terminal, wherein the current source is configured to provide the limited current flowing through the sensing resistor.

19. The current sense method of claim 16, wherein the first signal is at a voltage level higher than a reference voltage when the first power switch is turned on.

20. The current sense method of claim 18, wherein the first signal is at a voltage level lower than the reference voltage when the first power switch is turned off.
